(19) United States
(12) Patent Application Publication
(10) Pub. No.: US 2023/0332276 A1
(43) Pub. Date: Oct. 19, 2023

(54) Method for Producing and Designing Complex Three-Dimensional Magnetic Shielding Elements, Shielding Elements, and the Use Thereof

(71) Applicants: voestalpine Metal Forming GmbH, Krems an der Donau (AT); Mogema BV, GS Het Harde (NL)

(72) Inventors: Bas-Jan Hoogenberg, Zwolle (NL); Robert Vehof, Deventer (NL); Brian Brady, Amersfoort (NL); Guillermo Domínguez, Amerfoort (NL); Karl Radlmayr, Steyregg (AT)

(21) Appl. No.: 18/245,645

(22) PCT Filed: Sep. 16, 2021
(86) PCT No.: PCT/EP2021/075544

§ 371 Date: Mar. 16, 2023

(30) Foreign Application Priority Data
Sep. 16, 2020 (DE) 10 2020 124 189.5

(51) Int. Cl. C22C 19/05; C22F 1/10; C22C 38/02; C22C 38/04; C22C 38/06; C22C 38/30; C22C 38/28; C22C 38/26; C22C 38/24; C22C 38/22; C21D 9/46; C21D 8/12; C21D 6/00; B33Y 10/00; B33Y 80/00; B22F 5/00; B33Y 40/20; B22F 10/64; H05K 9/00; B21D 22/02

(52) U.S. Cl. CPC C22C 19/057; C22F 1/10; C22C 38/02; C22C 38/04; C22C 38/06; C22C 38/30; C22C 38/28; C22C 38/26; C22C 38/24; C22C 38/22; C21D 9/46; C21D 8/1216; C21D 8/1244; C21D 6/002; C21D 6/005; C21D 6/007; C21D 6/008; B33Y 10/00; B33Y 80/00; B22F 5/006; B33Y 40/20; B22F 10/64; H05K 9/0075; B21D 22/022; C22C 2202/02; B22F 2998/10

(57) ABSTRACT

A method for producing three-dimensional magnetic shields with a sufficient permeability from unannealed, soft-annealed, or magnetization annealed magnetically soft metal sheets, wherein the metal sheet is either cold formed into the three-dimensional component in a one-step or multi-step process, then is subjected to a (magnetization) annealing to increase the permeability, and is then transferred to a forming tool, in which it is held and/or pressed in a tool, which has the desired contour of the component, and is optionally shape-corrected or calibrated by the tool, and allowed to cool in the tool, or a sheet is heated and then formed to the desired geometry in a hot-forming tool and held in it, and is allowed to cool in the tool, or the three-dimensional component is generated by additive production and then is subjected to a (magnetization) annealing to increase the permeability; the invention also relates to a shielding device.

### FIELD OF THE INVENTION

The invention relates to a method for producing complex three-dimensional magnetic shields, devices for magnetic shielding, and the use thereof.

### BACKGROUND OF THE INVENTION

Materials with an extremely high magnetic permeability, in particular nickel-iron alloys, are used as magnetic shields because with a very high permeability of μᵣ=50,000-140,000, they concentrate the magnetic flux of particularly low-frequency magnetic fields. Such materials are also referred to as magnetically soft materials. When metals of this kind are bent, deformed, or mechanically worked, though, the very high permeability drops drastically, possibly resulting in values of as low as μᵣ=150.

This extreme loss of permeability can be rectified again through a subsequent heat treatment; it is even possible to enhance the permeability. The heat treatment time, though, is relatively long and the temperature is quite high, which can encourage the material to flow, a completely undesirable effect, particularly in the case of deformed materials. For this reason, such parts are usually clamped and then heated to 1,000-1,400° C.

To achieve magnetic shielding it is known, for example, for sheets that are made of such a material to be bent in the manner disclosed in U.S. Pat. No. 4,331,285. It is also known for such materials to be cut with a water jet or laser or for them to be deep-drawn (JP 11186019 A).

U.S. Pat. No. 6,813,364 B1 has disclosed a simple deep drawing method for small parts.

WO2014/090282 A1 has disclosed an electrical separation method.

CA 2080177 C has disclosed a transfer molding method for small parts.

In addition, it is also known to produce complex components by milling them out of solid material.

The object of the invention is to create a method with which complex three-dimensional magnetic shielding devices can be produced in a simple, inexpensive way.

Another object of the invention is to create a magnetic shielding device, which is inexpensively provided with a complex three-dimensional embodiment.

### SUMMARY OF THE INVENTION

The inventors have discovered that on the one hand in the high tech sector (among others, including semiconductor technology and electron microscopy) and on the other hand in the field of automotive applications, particularly due to the trend toward producing electric vehicles combined with autonomous driving, there is more and more demand for mechatronic systems with both a very high precision and accuracy and also high power outputs, which requires a higher ratio of magnetic shielding devices.

As has already been mentioned above, though, it is problematic that very large three-dimensional objects cannot be produced from these materials because in particular, the high temperature of 1,000-1,400° C. during the annealing on the one hand, and on the other hand, it is currently almost impossible to achieve relatively large surface areas and likewise also low thicknesses. The reason for this is that at the above-mentioned temperatures, these large components experience creeping and become deformed due solely to their size. Corresponding devices for avoiding creeping, which could support the components at different points are very complex and very expensive. It has also turned out that even with such devices, it is not possible to reliably prevent a deformation of complex components.

According to the invention, the method provides two possible processing routes in order to achieve complex three-dimensional magnetic shielding devices.

In a first processing route, the complex three-dimensionally shaped part is produced from the corresponding materials in a cold deep-drawing process. This complex three-dimensional part is then annealed in a vacuum or under a hydrogen atmosphere and then inserted in the hot state into a tool, which corresponds to the desired shape and desired geometry of the finished component and is held there until it is stable in terms of creeping and can be removed.

In this second step of the forming process, the shape deviation due to the creeping of the material is thus corrected during the annealing process. According to the invention, this does not cause a quenching of the material; instead, the molded part is held in its shape in the mold and is pressed. It can then cool in the mold; the mold is optionally preheated in order to set the optimum cooling rate.

It is advantageous that the parts have the absolutely correct shape, i.e. correspond to the desired geometry, even if this shape is three-dimensionally complex since deformations due to the creeping of the material cannot occur in this step. Since the optionally occurring shape correction, calibration, or forming still occurs at very high temperatures, the magnetic properties can be largely retained.

In a modification of the method, particularly if the material does not have a very high forming resistance, suitable components can be allowed to cool after the magnetization annealing and inserted into the tool at a suitable temperature, for example room temperature, and calibrated. In order to reduce negative influences on the permeability, the forming speed can optionally be adapted and in particular, an abrupt forming can be avoided and instead, a slower “in-mold pressing” can take place.

According to the second solution, a steel sheet or in particular a steel plate made of the magnetically soft material that has been annealed under vacuum or under a hydrogen atmosphere for the purpose of adjusting the permeability, is inserted in the hot state into a press tool in which the part is formed in one step and is held in the formed state and is cooled in the mold; the mold is optionally preheated in order to reduce the cooling speed.

In both cases, the tool can be preheated or heated during the cooling so that the cooling rate is adapted to the requirements of the magnetically soft material.

With the invention, it is advantageous that by the defined holding and cooling in a tool, which is shaped so that it corresponds to the finished component, and by the setting of cooling conditions, which permit an optimum magnetic permeability, it is possible to counteract creeping tendencies of the material, allowing the material to be produced so that it is dimensionally stable, accurate in shape, and has a high permeability. Shape changes in a cold, completely formed material that have occurred during the magnetization annealing can be corrected in the tool without diminishing the magnetic properties too significantly (i.e. in the vicinity of a factor of 10 or more).

The invention therefore relates to a method for producing three-dimensional magnetic shields with a sufficient permeability from unannealed, soft-annealed, or magnetization annealed magnetically soft metal sheets, wherein the metal sheet is either
cold formed into the three-dimensional component in a one-step or multi-step process, then is subjected to a (magnetization) annealing to increase the permeability, and is then transferred to a forming tool, in which, in the hot state or at room temperature, it is held and/or pressed in a tool, which has the desired contour of the component, and is optionally shape-corrected or calibrated by the tool, and is allowed to cool in the tool,
or
for purposes of the forming process and increasing permeability, a sheet is heated and then formed to the desired geometry in a hot-forming tool and held in it, and is allowed to cool in the tool,
or
the three-dimensional component is generated by additive production and then is subjected to a (magnetization) annealing to increase the permeability.

According to one embodiment, a sheet made of a magnetizable nickel-iron alloy, a magnetizable silicon-iron alloy, a magnetizable cobalt-iron alloy, or other magnetizable metal alloys is used as the magnetically soft metal sheet.

According to one embodiment, before the cold forming, after the cold forming, or before the hot forming, the sheet is subjected to a soft annealing.

According to one embodiment, with a nickel-iron alloy, the soft annealing is carried out at 600 to 900° C., in particular at 700 to 800° C.

According to one embodiment, with a nickel-iron alloy, the magnetization annealing is carried out at 1000 to 1400° C., in particular 1100 to 1300° C., in particular 1150° C.

According to one embodiment, with a nickel-iron alloy, the hot forming is carried out at 500 to 800° C., in particular 600 to 800° C., preferably 600° C.

According to one embodiment, with a nickel-iron alloy, the hot calibration is carried out at 500 to 800° C., in particular 600 to 800° C., preferably 600° C.

According to one embodiment, with a cobalt-iron alloy, the magnetization annealing is carried out at 700 to 950° C., in particular 730 to 900° C.

According to one embodiment, with a cobalt-iron alloy, the hot forming is carried out at 500 to 800° C., in particular 600 to 800° C.

According to one embodiment, with a cobalt-iron alloy, the hot calibration is carried out at 500 to 800° C., in particular 600 to 800° C.

According to one embodiment, with a silicon-iron alloy, the soft annealing is carried out at 600 to 950° C., in particular at 700 to 800° C.

According to one embodiment, with a silicon-iron alloy, the magnetization annealing is carried out at 700 to 1100° C., in particular 750 to 1050° C.

According to one embodiment, with a silicon-iron alloy, the hot forming is carried out at 500 to 800° C., in particular 600 to 800° C.

According to one embodiment, with a silicon-iron alloy, the hot calibration is carried out at 500 to 800° C., in particular 600 to 800° C.

According to one embodiment, with nickel-iron alloys, the cycle time for a soft annealing is 2 to 10 h.

According to one embodiment, with nickel-iron alloys, the cycle time for a magnetization annealing is 2 to 150 h.

According to one embodiment, with nickel-iron alloys, the cycle time for a hot forming is 1 sec. to 2 h.

According to one embodiment, with nickel-iron alloys, the cycle time for a hot calibration is 1 sec. to 2 h.

According to one embodiment, with nickel-iron alloys, the cycle time for a cold forming is 1 sec. to 2 h.

According to one embodiment, with nickel-iron alloys, the cycle time for a cold calibration is 1 sec. to 2 h.

According to one embodiment, with cobalt-iron alloys, the cycle time for a magnetization annealing is 2 to 150 h.

According to one embodiment, with cobalt-iron alloys, the cycle time for a hot forming is 1 sec. to 2 h.

According to one embodiment, with cobalt-iron alloys, the cycle time for a hot calibration is 1 sec. to 2 h.

According to one embodiment, with cobalt-iron alloys, the cycle time for a cold forming is 1 sec. to 2 h.

According to one embodiment, with cobalt-iron alloys, the cycle time for a cold calibration is 1 sec. to 2 h.

According to one embodiment, with silicon-iron alloys, the cycle time for a soft annealing is 0.25 to 10 h.

According to one embodiment, with silicon-iron alloys, the cycle time for a magnetization annealing is 0.5 to 10 h.

According to one embodiment, with silicon-iron alloys, the cycle time for a hot forming is 1 sec. to 2 h.

According to one embodiment, with silicon-iron alloys, the cycle time for a hot calibration is 1 sec. to 2 h.

According to one embodiment, with silicon-iron alloys, the cycle time for a cold forming is 1 sec. to 2 h.

According to one embodiment, with silicon-iron alloys, the cycle time for a cold calibration is 1 sec. to 2 h.

According to one embodiment, the forming speed, particularly for the hot forming, is a tool speed of preferably between 5 mm/min and 60 mm/min.

According to one embodiment, after the hot forming or after being held in the tool, the component is removed at a temperature at which the component is stable in terms of material flow and can cool in the air and is removed in particular at 200 to 600° C., in particular 300 to 500° C.

According to one embodiment, the sheet is produced out of a plurality of sheet bars by means of welds, in particular combinations of a plurality of sheet bars of different alloys, thicknesses, tempering grades, or annealing grades, particularly with regard to a soft annealing, solution annealing, and/or low-stress annealing.

According to one embodiment, the welded sheet bars are flat or three-dimensionally embodied components, which are welded to one another before, during, or after the process.

Another aspect of the invention relates to a shielding device made of a three-dimensionally embodied metal sheet with a high permeability or composed of a plurality of metal sheets, in particular produced according to one of the preceding methods, wherein the metal sheet is either
cold formed into the three-dimensional component in a one-step or multi-step process, then is subjected to a (magnetization) annealing to increase the permeability, and is then transferred to a forming tool, in which, in the hot state or at room temperature, it is held and/or pressed in a tool, which has the desired contour of the component, and is optionally shape-corrected or calibrated by the tool, and is allowed to cool in the tool,
or
for purposes of the forming process and increasing permeability, a sheet is heated and then formed to the desired geometry in a hot-forming tool and held in it, and is allowed to cool in the tool,
or
the three-dimensional component is generated by additive production and then is subjected to a (magnetization) annealing to increase the permeability.

According to one embodiment, the metal sheet consists of a magnetizable nickel-iron alloy, a magnetizable silicon-iron alloy, a magnetizable cobalt-iron alloy, or other magnetizable metal alloys.

According to one embodiment, in nickel-iron alloys, the nickel-iron content is between 30 and 90 wt %, wherein the nickel content is in particular between 50 and 80 wt %, wherein the nickel-iron alloy can contain other elements such as molybdenum and/or chromium in the vicinity of up to 10 wt % and other elements such as manganese, silicon, and/or carbon, each in the vicinity of up to 1 wt %, and the remainder consists of iron and inevitable impurities.

According to one embodiment, in silicon-iron alloys, the silicon content is between 0.1 and 8 wt %, wherein the silicon-iron alloy can contain up to 1 wt % manganese and up to 2 wt % aluminum and the remainder consists of iron and inevitable impurities.

According to one embodiment, in cobalt-iron alloys, the cobalt content is 9-60 wt %, preferably 10-27 wt %, wherein the cobalt-iron alloy can contain from 2 to 10 wt % chromium and can contain molybdenum, vanadium, niobium, tantalum, aluminum, zirconium, and/or manganese, each in the vicinity of up to 2 wt % and collectively totaling up to 5 wt %, and the remainder consists of iron and inevitable impurities.

Another aspect of the invention relates to the use of a shielding device of the above-described type for panels, linings, and shields composed of individual sheets or complex shielding components composed of a plurality of assembled sheets.

Another aspect of the invention relates to the use of a shielding device of the above-described type for embodying housings, chambers, compartments, and the like.

### BRIEF DESCRIPTION OF THE DRAWINGS

The invention will be explained by way of example based on the drawings; in the drawings:

FIG. 1: shows different processing sequences of embodiments with a separate forming and calibrating step for nickel-iron alloys;

FIG. 2: shows different processing sequences of embodiments with distinct forming steps for nickel-iron alloys;

FIG. 3: shows different processing sequences of embodiments with a separate forming and calibrating step for cobalt-iron alloys;

FIG. 4: shows different processing sequences of embodiments with distinct forming steps for cobalt-iron alloys;

FIG. 5: shows different processing sequences of embodiments with a separate forming and calibrating step for silicon-iron alloys;

FIG. 6: shows different processing sequences of embodiments without a soft annealing step for silicon-iron alloys;

FIG. 7: shows different processing sequences of embodiments with distinct forming steps for silicon-iron alloys.

### DETAILED DESCRIPTION

The invention relates to the complex 3D-forming of metal sheets composed for example of nickel-iron alloys that have magnetically soft properties. These materials inherently require a complex and costly processing due to a required heat treatment under controlled conditions at the end of the process. This heat treatment optimizes the magnetic properties, which are largely lost when the material is formed after the heat treatment.

According to the invention, a method is created, which supplements existing processing routes with additional processing steps that permit the use of a modified procedure and thus on the one hand make the process significantly more effective and in particular make it possible to dispense with a final heat treatment step after a required forming procedure.

The magnetically soft materials used according to the invention are characterized by a high magnetic permeability. The group of materials in this connection includes not only nickel-iron alloys, but also silicon-iron alloys, cobalt-iron alloys, and others.

Unless otherwise indicated, all percentages given are meant to express percentage by weight (wt %) and should be interpreted as such.

In nickel-iron alloys, the nickel content is 30-90 wt %. Materials of this kind exhibit an outstandingly high magnetic permeability of μᵣ≥1000 as a result of which they make it possible to allow a high magnetic flux density of the material. Although the original permeability is very high, it can be increased even further by the heat treatment that has already been mentioned above. Above 30 wt % nickel, the nickel-iron alloy is subject to a phase transformation from BCC to FCC. The FCC for the material is stable up to the melting point, which permits the use of very high heat treatment temperatures. The Curie temperature extends from 200° C. at 35 wt % nickel to a maximum of 600° C. at about 70 wt % nickel. Preferably, the nickel content can be between 50 and 80 wt %. The nickel-iron alloy can contain other elements such as molybdenum and/or chromium in the vicinity of up to 10%. The nickel-iron alloy can contain other elements such as manganese, silicon, and/or carbon, each in the vicinity of up to 1%.

The soft annealing can take place in a temperature range of 600-900° C. with a cycle time of 1-10 h; the magnetization annealing can take place in a temperature range of 1000-1400° C. with a cycle time of 0.5-150 h.

For purposes of the invention, the cycle time or treatment time is the total time in which the material is heat treated, i.e. including the heating time and cooling time. The cycle time can preferably be oriented on the thickness of the material, i.e. with thin sheets that are 0.1 mm thick, preferably the lower limit of the cycle time is used, whereas with thicker sheets that are >5 mm thick, it is possible to work toward the upper limit.

For silicon-iron alloys, the silicon content is typically 0.1-8 wt %. With a silicon content above 2 wt %, only the BCC phase is present up to the melting point, which permits a high-temperature treatment to be used here as well. The Curie temperature extends from 660° C. at 8 wt % silicon to a maximum of 770° C. in the absence of silicon. The silicon-iron alloys can contain up to 1% manganese and up to 2% aluminum.

With these alloys, the soft annealing can preferably take place in the temperature range of 550-750° C. The cycle time can be between 10 min and 10 h.

With certain alloys, the optional soft annealing can ensure a further improvement in the forming behavior. To be able to ensure a good forming behavior in grades with a lower Si content, preferably below 1.5%, a cold forming can be preferable to the soft annealing as a first processing step and in highly alloyed Si alloys, preferably above 1.5% Si, a hot forming can be preferable to the soft annealing as a first processing step. The magnetization annealing can take place in the temperature range of 750-1050° C.; the cycle time is preferably 5 sec to 10 h. In a continuous annealing process, the cycle time can be set at 5 sec. to 30 sec., which can reduce the manufacturing time. In a bell annealing process, the cycle time can be between 1 h and 10 h.

In cobalt-iron alloys, the cobalt content is 9-60 wt %, preferably 10-27 wt %. A high magnetic saturation of up to 2.4 T is characteristic of these alloys. Although the permeability does not exceed that of nickel-iron alloys (less than approximately 20,000μ), because of the high saturation, it is a preferred choice for achieving a high flux density in magnetic shields or other flux conductors (e.g. actuators). The Curie temperature extends from 850° C. at 9 wt % cobalt to a maximum of 980° C. at about 40 wt % cobalt. At about 900-950° C., the cobalt-iron alloy is subject to a phase transformation from BCC (ferrite) to FCC (austenite); consequently, the heat treatment should preferably take place at temperatures above 900° C. In addition, with a concentration of 50/50 wt % cobalt-iron, at a temperature below 730° C., a phase transformation to a so-called B2 superlattice occurs, which causes the brittleness to increase sharply. For this reason, the desired temperature for complex forming operations lies between these two phase transformations. The cobalt-iron alloy can contain other elements such as chromium. Chromium increases the corrosion protection and is preferably added to the alloy in the range from 2 to 10%. Other elements such as molybdenum, vanadium, niobium, tantalum, aluminum, zirconium, and/or manganese, each in the vicinity of up to 2% and collectively totaling up to 5%, can be added to the alloy.

Materials that are able to absorb and guide magnetic flux lines are required when it is necessary to shield against magnetic fields. This relates, for example, to precision sensor instruments in which magnetic fields could produce parasitic effects. Examples include scientific applications (electron microscopes, atomic force microscopes, etc.), medical devices, the energy sector, semiconductors (sub-nanometer, precision mechatronics), and others. In addition, it is foreseeable that the transition to electrically driven vehicles and the transition to autonomous driving will require much stronger magnetic shields in both type and size since the high voltages in DC-current motors have a negative impact on the electronics that are in particular used to analyze the surrounding traffic.

As has already been explained above, such materials are customarily subjected to a final annealing in order to once again bring them into a very high magnetically soft state with a very high magnetic permeability; this, however, results in the fact that complex forms cannot be produced.

According to the invention, a heat treatment is provided in which a nickel-iron alloy is heated, typically to 700° C.-800° C., for a certain amount of time. This temperature is above the so-called recrystallization temperature for the respective material. This recrystallization annealing is usually performed for 0.5 to 10 hours and the result is a material softening and an increased ductility (except for the cobalt alloy), the purpose of which is to prepare the material for subsequent procedures. In the following, this process is referred to as soft annealing.

In addition, when nickel-iron alloys are used, a high-temperature heat treatment is provided, which likewise heats the material for a certain period of time, wherein the temperature range of 1000° C.-1400° C., in particular 1050° C., is maintained for a time of 1 to 6 hours. During this treatment time, the crystals in the material grow to a size at which they can easily be seen by the naked eye. This process improves the shielding properties significantly due to the increase in the permeability (μ) even by a factor of up to 10 or more. Preferably, this heating is performed in a vacuum or in a hydrogen atmosphere, wherein both of the processes, whether in a vacuum or in a hydrogen atmosphere, serve to eliminate impurities. The removal of impurities in turn enables a greater and more extensive grain growth. In the following, this process is referred to as magnetization annealing. In general, the cycle time of the first soft annealing can preferably elapse more quickly, i.e. can be shorter, than that of the possibly subsequent magnetization annealing. This can encourage the structure formation.

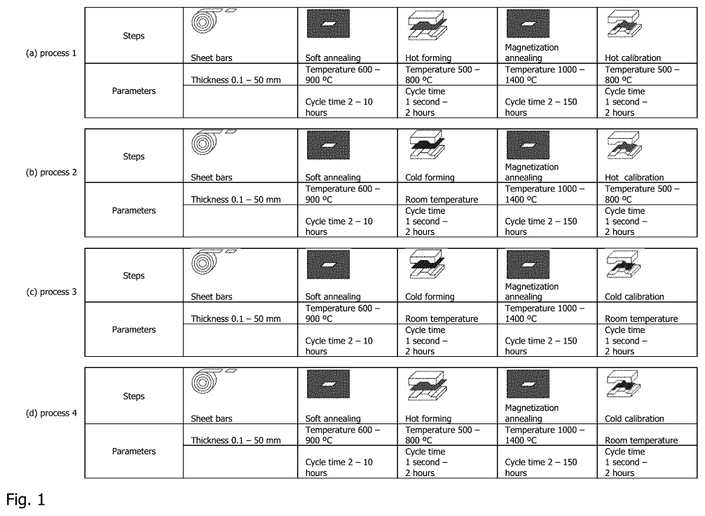

FIG. 1(a) shows a possible process sequence for nickel-iron alloys. A sheet made of an alloy with adjustable magnetically soft properties, for example a nickel-based alloy with a thickness of 0.1 to 50 mm is first subjected to a soft annealing.

Then a shaping takes place in either the cold or hot state. With a cold forming (for example shown in FIG. 1 (b)), this takes place in a one-step or multi-step process until the finished component is achieved. In the hot state, a one-step forming is carried out at temperatures from 500 to 800° C.

For the hot forming, the heat from the soft annealing can be used or a new heating can be carried out.

For both possible processing routes, the magnetization annealing occurs next, which is used to adjust the permeability. This takes place at 1000 to 1400° C. for 1 to 6 hours. Then the formed body that is obtained in this way is subjected to a hot calibration or shape correction at 500 to 800° C. or is subjected to a shape stabilization in the hot state in a tool that is suitable for this purpose. In order to simplify the production effort and ensure a robust method, the calibration can also be carried out in the cold state. This is shown in FIGS. 1 (c) and 1 (d).

This means that the formed bodies, which may possibly have warped due to the magnetization heat treatment or in which creeping has occurred in the hot state of the material due to the influence of heat or due to their own weight, are brought back into the desired geometry. For this purpose, the tool has the appropriate geometry, which corresponds to the desired geometry of the formed component. It is therefore not possible to carry out a complete forming, but rather an adaptation or calibration of the shape. The heat of the component from the magnetization annealing can naturally also be used for this purpose. In particular, the cooling speed can be set so as to shape the cooling curve so that a maximal permeability is retained.

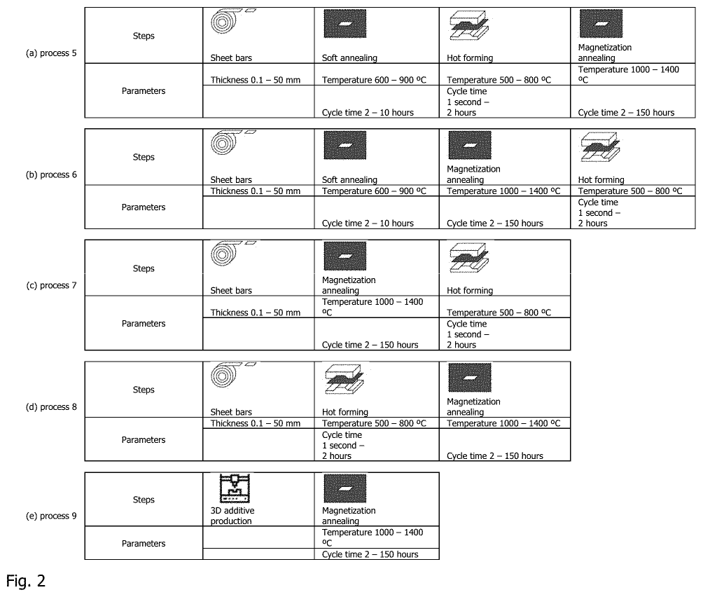

In another advantageous embodiment of the method (FIG. 2(a)), the first shaping step is omitted and in this case, the magnetization annealing is performed immediately after the soft annealing, wherein a subsequent forming step is performed, particularly using the heat from the magnetization annealing. This shaping step is preferably embodied so that the sheet bar of the sheet is hot formed in one step and is then held in the tool and allowed to cool, at least until mechanical stability is achieved and for as long as the cooling speed is required in order to maintain the permeability.

In another advantageous embodiment (FIG. 2(b)), the sheet bar is subjected to the magnetization annealing directly so that the soft annealing is integrated into this step. The final shaping then corresponds to the above-described embodiment.

All of the above-mentioned steps can be followed by cutting, milling, drilling, welding, surface, and cleaning steps; moreover, components made of sheet metal can also have additional layers or volumes applied to them in additive fashion, for example by means of 3D printing.

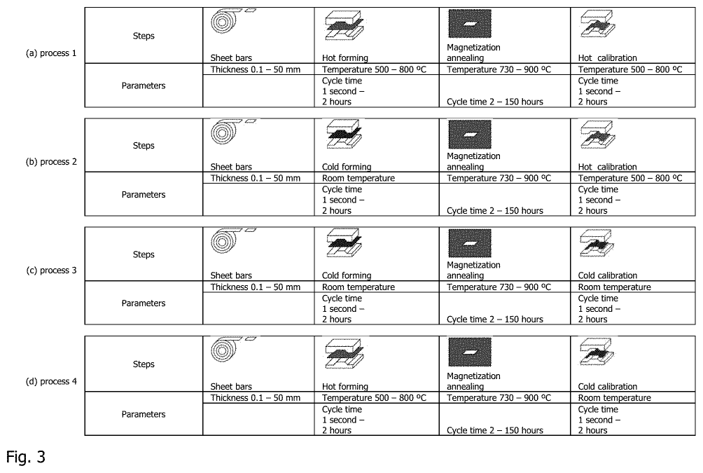

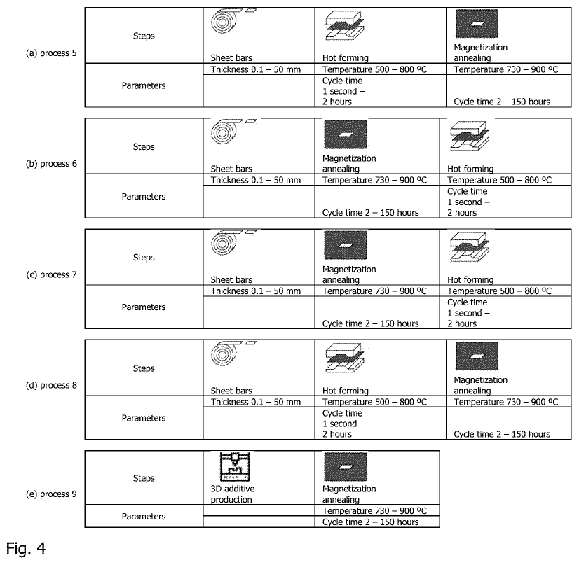

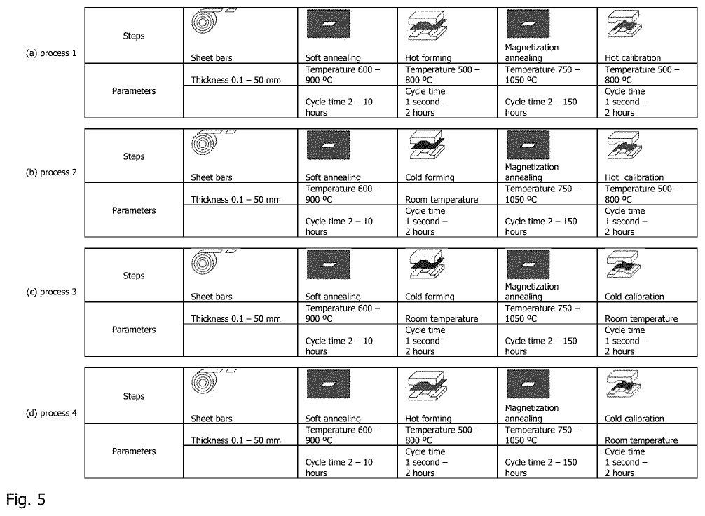

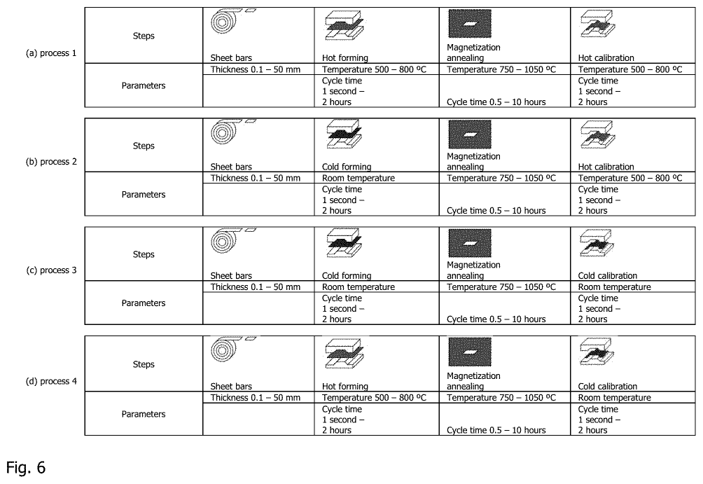

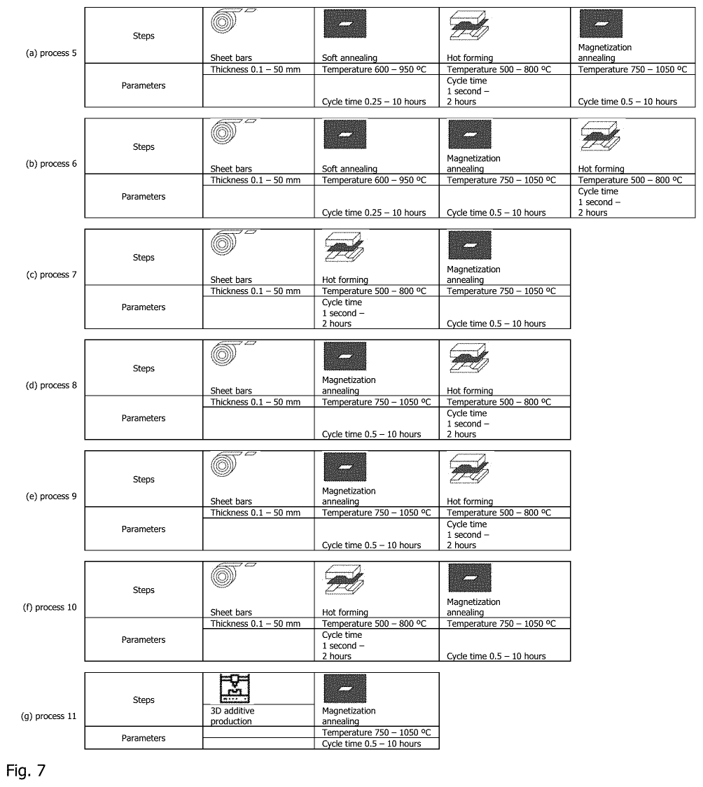

FIGS. 3 to 7 show possible production routes for other alloy compositions. FIGS. 3 and 4 show the possible route for cobalt-iron alloys and FIGS. 5 to 7 the possible routes for silicon-iron alloys.

With the invention, it is advantageous that the shaping of monolithic complex components has functional advantages as compared to the prior art in that the parts are cold formed and then heat treated. The combination of the heat treatment step and the hot forming results in exactly formed components with a high magnetic shielding action. The hot forming while maintaining the required temperatures also makes it possible to achieve complex shaping, which is advantageous particularly when there is limited installation space, for example in the electromobility sector.

With the invention, it is therefore possible to also produce complex components. Such components can then also be combined to produce complex shielding devices, for example entire housings, panels, chambers, and the like. In this connection, the complex components or shielding devices can also be embodied using different material thicknesses. An example of this is shown in the following table.

| Application | Product thickness | | Starting material |
|---|---|---|---|
| shields, panels, linings | 0.05-5.00 | mm | sheet bars, metal powder, |
| | | | metal wire |
| chambers, compartments | 2-50 | mm | sheet bars, metal powder, |
| | | | metal wire |

For example, sheet bars with a length of up to 3500 mm and a width of up to 2500 mm can be produced from a soft annealed nickel-iron alloy with a Ni content of 48 wt % and can be formed into a three-dimensional shield. All fusion welding methods can be used as the joining method for producing large sheet bars of this kind, preferably laser welding.

To test the invention, sheet bars 2 mm thick made of a nickel-iron alloy with a Ni content of 48 wt % were formed by means of cold forming, i.e. deep drawn, at room temperature into a spherical dome shape with a depth of 50 mm and a diameter of 100 mm. This deformation diminishes the magnetic properties and for this reason, a person skilled in the art would not use this part as a magnetic shielding element. Parts of this kind are used to demonstrate the effect of the invention and are therefore referred to as reference parts.

This process was selected for a uniform distribution of stress and elongation. Other parts were formed to a drawing depth of 48 mm (and 100 mm diameter) using the same process. These parts are test parts for characterizing the calibration process and after the thermal treatment, undergo a final drawing to 50 mm. The magnetic properties of the testing and reference parts were characterized prior to the heat treatment.

The testing and reference parts were collectively subjected to a magnetization annealing at 1150° C. for a time of 4 hours under a hydrogen atmosphere. After this processing step, the reference parts are complete (the parts are produced in accordance with FIG. 1 (c)).

The test parts (48 mm) underwent final drawing by means of cold forming, i.e. deep drawing at room temperature, to a depth of 50 mm and a diameter of 100 mm; in this step, a calibration of 2 mm (from 48 mm to 50 mm) takes place, which results in a calculated total elongation of approx. 4% (the parts are produced in accordance with the process shown in FIG. 1 (c)). Between the final drawing and the next process steps, the magnetic properties of the test parts were characterized once again. After the final drawing, these test parts were subjected to a second magnetization annealing at 1150° C. for a time of 4 hours under a hydrogen atmosphere and were tested for their magnetic properties.

The characterization showed that the magnetic shield had the best values after the magnetization annealing. Without a shield, a magnetic flux of 36.7 mT was measured. In the reference parts, this value is reduced to 58 μT (with a reduction factor of 633) after the magnetization annealing, whereas before the annealing, a value of 1.8 mT was measured in the reference parts (this corresponds to a reduction factor of 20). The annealing offers a more than 30-fold improvement in the shielding in comparison to an exclusively cold-formed part.

In the test parts with a cold calibration step (4% elongation), after the magnetization annealing, a magnetic flux of 418 μT was measured (reduction factor 92). With this result, the shielding in this case is approx. 4.5×better than without magnetization annealing, but approx. 6×worse than in the annealed reference parts.

This elongation of 4% is a very high value for a calibration step and in real parts, occurs at most very locally. It was nevertheless possible to achieve good properties with the method according to the invention. Usually in practice, deformations occur only in radius-adjacent free forming zones without punch contact, as a result of which large regions remain largely free of deformation.

In another test, a significantly larger magnetic shield according to the invention was produced and characterized (approx. 600×300×80 mm). From a soft-annealed 48 wt % nickel-iron alloy sheet with a 2 mm thickness, a dome-shaped geometry was produced and geometrically characterized in a forming step at room temperature.

The component was subjected to a magnetization annealing at 1150° C. for a time of 4 hours under a hydrogen atmosphere. Then, a magnetic and geometric characterization was carried out. The geometric dimensions have a deviation of 1% from the geometry after the first forming step. This is attributable to the creeping during the magnetization annealing.

In order to produce the target geometry once again, a deep-drawing calibration process was performed at room temperature. In this case, a local elongation of approx. 0.7% in the radii of the component occurred (the parts were produced in accordance with the process in FIG. 1 (c)).

The magnetic characterization shows that with a relatively high magnetic flux density of 1.2 mT, the products according to the invention achieve a 9% lower magnetic shielding in comparison to the annealed parts before the calibration. With a lower flux density of approx. 300 μT, no difference was measured. This is explained by the fact that with the lower flux density, no (local) saturation occurs.

These two examples show that the presented method with a calibration step can have powerful local effects on the permeability, but overall, can achieve a favorably functioning shield. Furthermore, with this method, the shape corresponds to the desired geometry in the test parts, whereas in the reference parts, there is a shape deviation due to creeping of the material. With a calibration step, it is possible to produce extremely exact and complex geometries, which are advantageous in the case of applications with limited installation space or those involving miniaturization.

1. A method for producing a three-dimensional magnetic shield with a sufficient permeability, comprising:
using an unannealed, soft-annealed, or magnetization annealed magnetically soft metal sheet, and either:
cold forming the metal sheet into the three-dimensional component in a one-step or multi-step process, then subjecting the three-dimensional component to a magnetization annealing to increase the permeability, and then transferring the three-dimensional component to a forming tool, in which, in a hot state or at room temperature, the three-dimensional component is held and/or pressed in the forming tool, which has a desired contour of the component, and the three-dimensional component is optionally shape-corrected or calibrated by the forming tool, and is allowed to cool in the forming tool, or
for purposes of the forming process and increasing permeability, heating the metal sheet and then forming the metal sheet to a desired geometry in a hot-forming tool and holding the formed metal sheet in the hot-forming tool, and allowing the formed metal sheet to cool in the hot-forming tool, or
generating the three-dimensional component by additive production and then subjecting the three-dimensional component to a magnetization annealing to increase the permeability.

2. The method according to claim 1, comprising using a sheet made of a magnetizable nickel-iron alloy, a magnetizable silicon-iron alloy, a magnetizable cobalt-iron alloy, or other magnetizable metal alloy as the magnetically soft metal sheet.

3. The method according to claim 1, comprising subjecting the metal sheet to a soft annealing before the cold forming, after the cold forming, or before the hot forming.

4. The method according to claim 3, wherein the metal sheet is made of a nickel-iron alloy, and the soft annealing is carried out at 600 to 900° C.

5. The method according to claim 1, wherein the metal sheet is made of a nickel-iron alloy, and the magnetization annealing is carried out at 1000 to 1400° C.

6. The method according to claim 1, wherein the metal sheet is made of a nickel-iron alloy, and the hot forming is carried out at 500 to 800° C.

7. The method according to claim 1, wherein the metal sheet is made of a nickel-iron alloy, and the hot calibration is carried out at 500 to 800° C.

8. The method according to claim 1, wherein the metal sheet is made of a cobalt-iron alloy, and the magnetization annealing is carried out at 700 to 950° C.

9. The method according to claim 1, wherein the metal sheet is made of a cobalt-iron alloy, and the hot forming is carried out at 500 to 800° C.

10. The method according to claim 1, wherein the metal sheet is made of a cobalt-iron alloy, and the hot calibration is carried out at 500 to 800° C.

11. The method according to claim 3, wherein the metal sheet is made of a silicon-iron alloy, and the soft annealing is carried out at 600 to 950° C.

12. The method according to claim 1, wherein the metal sheet is made of a silicon-iron alloy, and the magnetization annealing is carried out at 700 to 1100° C.

13. The method according to claim 1, wherein the metal sheet is made of a silicon-iron alloy, and the hot forming is carried out at 500 to 800° C.

14. The method according to claim 1, wherein the metal sheet is made of a silicon-iron alloy, and the hot calibration is carried out at 500 to 800° C.

15. The method according to claim 2, wherein with the nickel-iron alloy, a cycle time is 2 to 10 h for a soft annealing, 2 to 150 h for a magnetization annealing, 1 sec. to 2 h for a hot forming, 1 sec. to 2 h for a hot calibration, 1 sec. to 2 h for a cold forming, and 1 sec. to 2 h for a cold calibration.

16. The method according to claim 2, wherein with the cobalt-iron alloy, a cycle time is 2 to 150 h for a magnetization annealing, 1 sec. to 2 h for a hot forming, 1 sec. to 2 h for a hot calibration, 1 sec. to 2 h for a cold forming, and 1 sec. to 2 h for a cold calibration.

17. The method according to claim 2, wherein with the silicon-iron alloy, a cycle time is 0.25 to 10 h for a soft annealing, 0.5 to 10 h for a magnetization annealing, 1 sec. to 2 h for a hot forming, 1 sec. to 2 h for a hot calibration, 1 sec. to 2 h for a cold forming, and 1 sec. to 2 h for a cold calibration.

18. The method according to claim 1, wherein a forming speed, for the hot forming, is a tool speed of between 5 mm/min and 60 mm/min.

19. The method according to claim 1, wherein after the hot forming or after being held in the tool, the three-dimensional component is removed at a temperature of 200 to 600° C. at which the three-dimensional component is stable in terms of material flow and can cool in the air.

20. The method according to claim 1, wherein the metal sheet is produced out of a combination of a plurality of sheet bars of different alloys, thicknesses, tempering grades, or annealing grades with regard to a soft annealing, solution annealing, and/or low-stress annealing, and the plurality of sheet bars are welded together.

21. The method according to claim 20, wherein the welded sheet bars are flat or three-dimensionally embodied components, which are welded to one another before, during, or after the process.

22. A shielding device comprising:
a three-dimensionally embodied metal sheet with a high permeability composed of one or more metal sheets, wherein the three-dimensionally embodied metal sheet is either
cold formed into the three-dimensional component in a one-step or multi-step process, then is subjected to a magnetization annealing to increase the permeability, and is then transferred to a forming tool, in which, in a hot state or at room temperature, the metal sheet is held and/or pressed in a tool, which has a desired contour of the component, and is optionally shape-corrected or calibrated by the tool, and is allowed to cool in the tool, or
for purposes of the forming process and increasing permeability, the metal sheet is heated and then formed to a desired geometry in a hot-forming tool and held in the hot-forming tool, and is allowed to cool in the tool, or
the three-dimensional component is generated by additive production and then is subjected to a magnetization annealing to increase the permeability.

23. The shielding device according to claim 22, wherein the metal sheet consists of a magnetizable nickel-iron alloy, a magnetizable silicon-iron alloy, a magnetizable cobalt-iron alloy, or other magnetizable metal alloys.

24. The shielding device according to claim 23, wherein in nickel-iron alloys, the nickel-iron content is between 30 and 90 wt %, wherein the nickel content is between 50 and 80 wt %, wherein the nickel-iron alloy can contain other elements including molybdenum and/or chromium in a vicinity of up to 10 wt % and other elements including manganese, silicon, and/or carbon, each in a vicinity of up to 1 wt %, and a remainder consists of iron and inevitable impurities.

25. The shielding device according to claim 23, wherein in silicon-iron alloys, the silicon content is between 0.1 and 8 wt %, wherein the silicon-iron alloy can contain up to 1 wt % manganese and up to 2 wt % aluminum and a remainder consists of iron and inevitable impurities.

26. The shielding device according to claim 23, wherein in cobalt-iron alloys, the cobalt content is 9-60 wt %, wherein the cobalt-iron alloy can contain from 2 to 10 wt % chromium and can contain molybdenum, vanadium, niobium, tantalum, aluminum, zirconium, and/or manganese, each in a vicinity of up to 2 wt % and collectively totaling up to 5 wt %, and a remainder consists of iron and inevitable impurities.

27. A method of using a shielding device according to claim 22, comprising using the shielding device for panels, linings, and shields composed of individual sheets or complex shielding components composed of a plurality of assembled sheets.

28. A method of using a shielding device according to claim 22, comprising using the shielding device for embodying housings, chambers, and/or compartments.
